(19) United States
(12) Patent Application Publication
(10) Pub. No.: US 2021/0159289 A1
(43) Pub. Date: May 27, 2021

(54) DISPLAY SUBSTRATE, METHOD FOR MANUFACTURING DISPLAY SUBSTRATE AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventor: Xiaoning Liu, Beijing (CN)

(21) Appl. No.: 17/256,376

(22) PCT Filed: May 15, 2020
(86) PCT No.: PCT/CN2020/090659

§ 371 Date: Dec. 28, 2020

(30) Foreign Application Priority Data
May 22, 2019 (CN) 201910430796.7

(51) Int. Cl. H01L 27/32; H01L 51/52

(52) U.S. Cl. CPC H01L 27/3246; H01L 51/5228; H01L 51/5234; H01L 51/5218

(57) ABSTRACT

Provided is a display substrate, including a base substrate, wherein a displaying area of the base substrate is provided with a light-emitting area and a non-light-emitting area surrounding the light-emitting area; an auxiliary electrode layer on the base substrate, wherein the auxiliary electrode layer includes an auxiliary electrode pattern in the non-light-emitting area; and a first electrode layer, a light-emitting layer and a second electrode layer which are stacked on the base substrate along a direction away from the base substrate, wherein the auxiliary electrode pattern is electrically connected to the second electrode layer.

### CROSS-REFERENCE TO RELATED APPLICATIONS

This application is a 371 of PCT Application No. PCT/CN2020/090659, filed on May 15, 2020, which claims priority to Chinese Patent Application 201910430796.7, filed on May 22, 2019 and entitled “DISPLAY SUBSTRATE AND MANUFACTURING METHOD THEREFOR, AND DISPLAY APPARATUS”, the entire content of which is incorporated herein by reference.

### TECHNICAL FIELD

The present disclosure relates to the field of display technologies, and in particular relates to a display substrate, a method for manufacturing the display substrate and a display device.

### BACKGROUND

Organic light emitting diode (OLED) display devices have been widely used due to such characteristics as spontaneous illumination, low driving voltage and fast response.

### SUMMARY

The present disclosure provides a display substrate, a method for manufacturing the display substrate and a display device.

In one aspect, a display substrate is provided. The display substrate includes:

a base substrate, wherein a displaying area of the base substrate is provided with a light-emitting area and a non-light-emitting area surrounding the light-emitting area;

an auxiliary electrode layer on the base substrate, wherein the auxiliary electrode layer includes an auxiliary electrode pattern in the non-light-emitting area; and

a first electrode layer, a light-emitting layer and a second electrode layer which are stacked on the base substrate along a direction away from the base substrate,

wherein the auxiliary electrode pattern is electrically connected to the second electrode layer.

In some embodiments, the display substrate further includes a conductive structure disposed in the non-light-emitting area of the base substrate, wherein the conductive structure is in contact with a sidewall of the auxiliary electrode pattern and with the second electrode layer, respectively.

In some embodiments, an included angle between the sidewall of the auxiliary electrode pattern and a carrying surface of the base substrate ranges from 30° to 60°.

In some embodiments, the conductive structure is a conductive adhesive.

In some embodiments, a gap is provided between a portion of the light-emitting layer located in the non-light-emitting area and the sidewall of the auxiliary electrode pattern, and the gap is filled with the conductive structure.

In some embodiments, the auxiliary electrode layer and the first electrode layer are located in a same layer and spaced apart from each other; and

the auxiliary electrode pattern is provided with a first via hole, and the conductive structure is at least partially disposed in the first via hole.

In some embodiments, an orthographic projection of an opening on a side, proximal to the base substrate, of the first via hole onto the base substrate is located within an orthographic projection of the opening on a side, distal from the base substrate of the first via hole onto the base substrate.

In some embodiments, the display substrate further includes: a pixel definition pattern on a side, distal from the base substrate, of the first electrode layer, wherein the pixel definition pattern is provided with a second via hole which is communicated with the first via hole; and

an orthographic projection of the second via hole onto the base substrate is located within the orthographic projection of the first via hole onto the base substrate.

In some embodiments, the first electrode layer includes a reflective metal layer and a transparent electrode layer which are stacked on the base substrate along the direction away from the base substrate.

In some embodiments, the display substrate further includes: a pixel definition pattern on a side, distal from the base substrate, of the first electrode layer. The pixel definition pattern is provided with a second via hole which is communicated with the first via hole. An area of the orthographic projection of the first via hole onto the base substrate is larger than that of the orthographic projection of the second via hole onto the base substrate, and the orthographic projection of the second via hole onto the base substrate is located within the orthographic projection of the first via hole onto the base substrate.

The first electrode layer includes a reflective metal layer and a transparent electrode layer which are stacked along the direction away from the base substrate.

In some embodiments, the first electrode layer is located on a side, distal from the base substrate, of the auxiliary electrode layer, and the auxiliary electrode layer further includes a reflection pattern disposed in the light-emitting area.

In some embodiments, the first electrode layer includes a first electrode pattern and a second electrode pattern which are spaced apart with each other; wherein

the first electrode pattern is located on a side, distal from the base substrate, of the reflection pattern, and the second electrode pattern is located on a side, distal from the base substrate, of the auxiliary electrode pattern, and an orthographic projection of the second electrode pattern onto the base substrate covers an orthographic projection of the auxiliary electrode pattern onto the base substrate.

In another aspect, a method for manufacturing a display substrate is provided. The method includes:

forming an auxiliary electrode layer and a first electrode layer on a base substrate, wherein a displaying area of the base substrate is provided with a light-emitting area and a non-light-emitting area surrounding the light-emitting area, and the auxiliary electrode layer includes an auxiliary electrode pattern located in the non-light-emitting area;

forming a light-emitting layer on a side, distal from the base substrate, of the first electrode layer; and

forming a second electrode layer on a side, distal from the base substrate, of the light-emitting layer, wherein the second electrode layer is electrically connected to the auxiliary electrode pattern.

In some embodiments, forming the auxiliary electrode layer and the first electrode layer on the base substrate includes:

forming an auxiliary electrode film and the first electrode layer, which are located in a same layer, on the base substrate, wherein the auxiliary electrode film is located in the non-light-emitting area; and

forming a first via hole in the auxiliary electrode film by etching the auxiliary electrode film, to obtain the auxiliary electrode layer.

In some embodiments, forming the auxiliary electrode layer and the first electrode layer on the base substrate includes:

forming an auxiliary electrode film on the base substrate;

forming a first electrode film on a side, distal from the base substrate, of the auxiliary electrode film; and

performing patterning process on the first electrode film and the auxiliary electrode film respectively, to obtain the auxiliary electrode layer and the first electrode layer;

wherein the auxiliary electrode layer further includes a reflection pattern disposed in the light-emitting area.

In some embodiments, after forming the light-emitting layer on the side, distal from the base substrate, of the first electrode layer, the method further includes:

forming a conductive structure in the non-light-emitting area of the base substrate, wherein the conductive structure is in contact with a sidewall of the auxiliary electrode pattern, and the second electrode layer is electrically connected to the auxiliary electrode pattern by the conductive structure.

In some embodiments, forming the conductive structure in the non-light-emitting area of the base substrate includes:

filling a conductive adhesive in the non-light-emitting area; and

forming the conductive structure by curing the conductive adhesive.

In some embodiments, forming the conductive structure in the non-light-emitting area of the base substrate includes:

evaporating a metal material at a gap between a portion of the light-emitting layer located in the non-light-emitting area and a sidewall of the auxiliary electrode layer by an oblique angle evaporating process, to obtain the conductive structure.

In some embodiments, before forming the light-emitting layer on the side, distal from the base substrate, of the first electrode layer, the method further includes:

forming a pixel definition film on a side, distal from the base substrate, of the first electrode layer; and

performing patterning process on the pixel definition film, to obtain a pixel definition pattern, wherein a portion of the pixel definition pattern located in the non-light-emitting area is provided with a second via hole, and the second electrode layer is electrically connected to the auxiliary electrode pattern through the second via hole.

In yet another aspect, the present disclosure provides a display device which includes any one of display substrates described in any one of the aspects.

### BRIEF DESCRIPTION OF THE DRAWINGS

FIG. 1 is a schematic structural diagram of a display substrate according to an embodiment of the present disclosure;

FIG. 2 is a schematic top view of a display substrate according to an embodiment of the present disclosure;

FIG. 3 is a schematic structural diagram of another display substrate according to an embodiment of the present disclosure;

FIG. 4 is a schematic structural diagram of yet another display substrate according to an embodiment of the present disclosure;

FIG. 5 is a schematic structural diagram of still another display substrate according to an embodiment of the present disclosure;

FIG. 6 is a flowchart of a method for manufacturing a display substrate according to an embodiment of the present disclosure;

FIG. 7 is a flowchart of another method for manufacturing a display substrate according to an embodiment of the present disclosure;

FIG. 8 is a schematic structural diagram showing that an auxiliary electrode film and a first electrode layer have been formed according to an embodiment of the present disclosure;

FIG. 9 is a schematic structural diagram showing that a pixel definition film has been formed according to an embodiment of the present disclosure;

FIG. 10 is a schematic structural diagram showing that a pixel definition pattern has been formed according to an embodiment of the present disclosure;

FIG. 11 is a schematic structural diagram showing that an auxiliary electrode layer has been formed according to an embodiment of the present disclosure;

FIG. 12 is a schematic structural diagram showing that a light-emitting layer has been formed according to an embodiment of the present disclosure;

FIG. 13 is a schematic structural diagram showing that a conductive structure has been formed according to an embodiment of the present disclosure;

FIG. 14 is a schematic structural diagram showing that another conductive structure has been formed according to an embodiment of the present disclosure;

FIG. 15 is a schematic structural diagram of still yet another display substrate according to an embodiment of the present disclosure;

FIG. 16 is a flowchart of yet another method for manufacturing a display substrate according to an embodiment of the present disclosure;

FIG. 17 is a schematic structural diagram showing that an auxiliary electrode film has been formed according to an embodiment of the present disclosure;

FIG. 18 is a schematic structural diagram showing that a first electrode film has been formed according to an embodiment of the present disclosure;

FIG. 19 is a schematic structural diagram showing that an auxiliary electrode layer and a first electrode layer have been formed according to an embodiment of the present disclosure;

FIG. 20 is a schematic structural diagram showing that another pixel definition film has been formed according to an embodiment of the present disclosure;

FIG. 21 is a schematic structural diagram showing that another pixel definition pattern has been formed according to an embodiment of the present disclosure;

FIG. 22 is a schematic structural diagram showing that another light-emitting layer has been formed according to an embodiment of the present disclosure;

FIG. 23 is a schematic structural diagram showing that yet another conductive structure has been formed according to an embodiment of the present disclosure; and

FIG. 24 is a schematic structural diagram showing that still another conductive structure has been formed according to an embodiment of the present disclosure.

### DETAILED DESCRIPTION

For clearer descriptions of the objects, technical solutions and advantages of the present disclosure, implementations of the present disclosure is described in further detail below in combination with the accompanying drawings.

An OLED display device includes an OLED display substrate. In related arts, the OLED display substrate includes a base substrate, and an anode layer, a light-emitting layer and a cathode layer which are stacked on the base substrate along a direction away from the base substrate. In a top-emitting OLED display substrate, light emitted from an emitting layer is reflected by the anode layer and then emitted from the cathode layer. Owing to that the light needs to be emitted from the cathode layer in the top-emitting OLED display substrate, it is required that the cathode layer is thin to ensure the light transmittance.

However, in the top-emitting OLED display substrates, the thin cathode layer causes a high self-resistance. Therefore, the display effect of the OLED display substrate in related arts is poor.

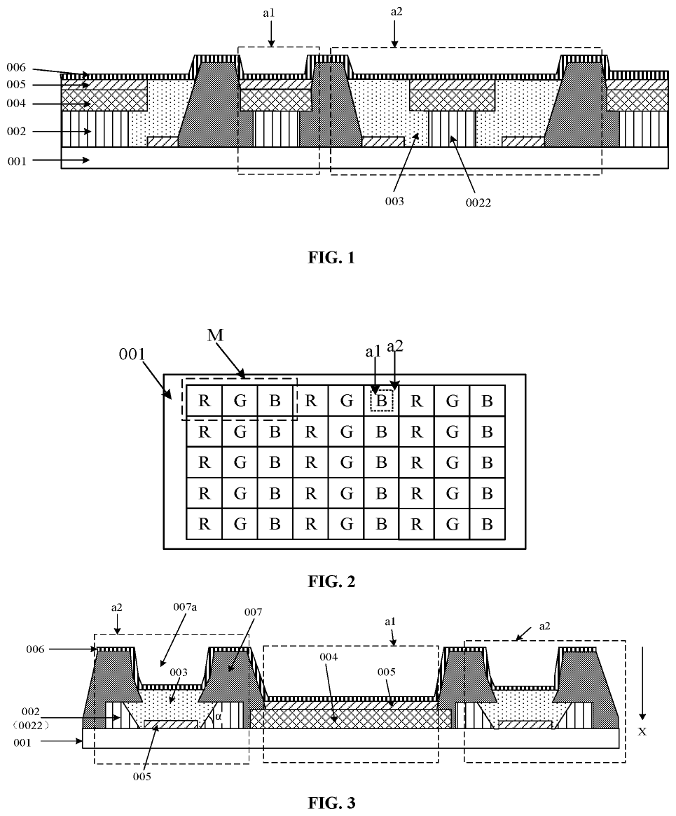

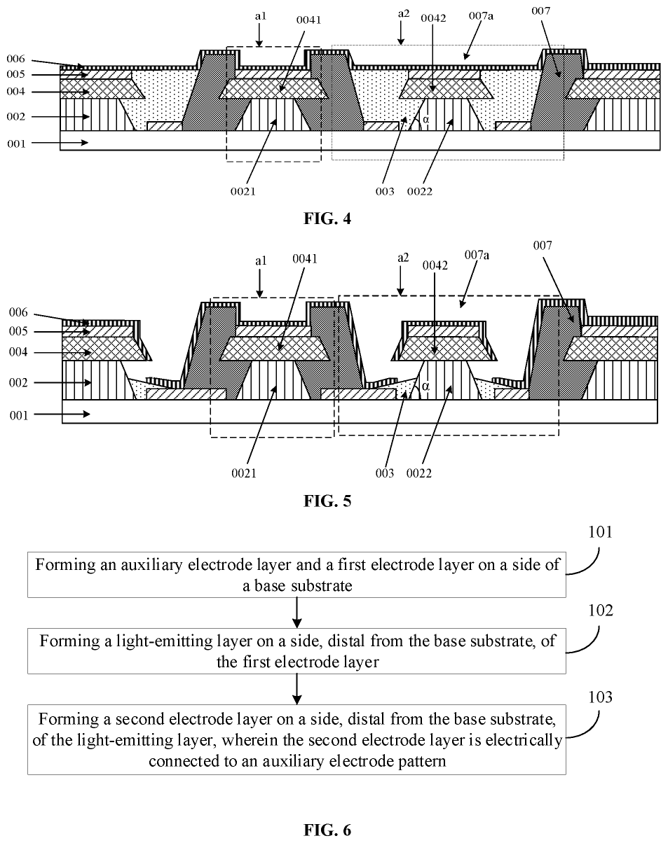

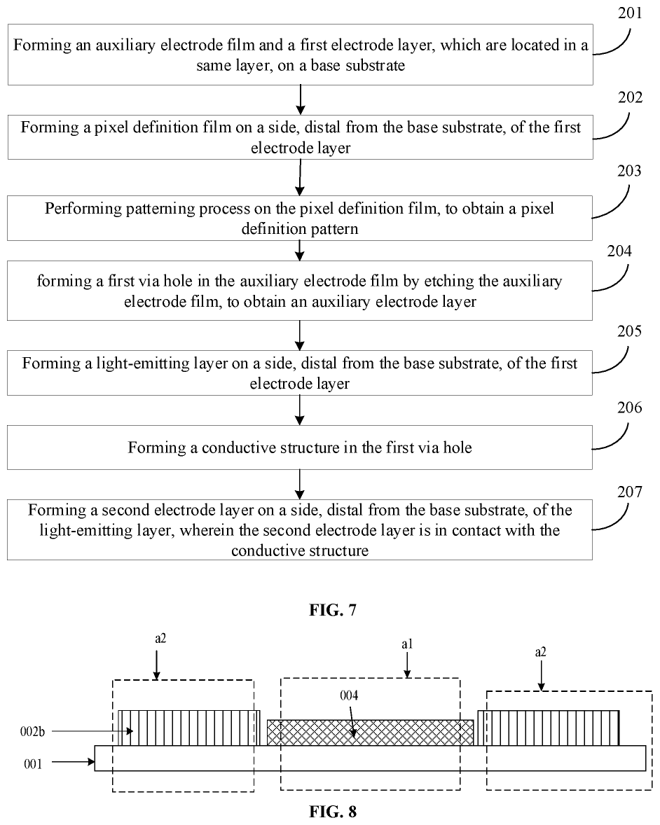

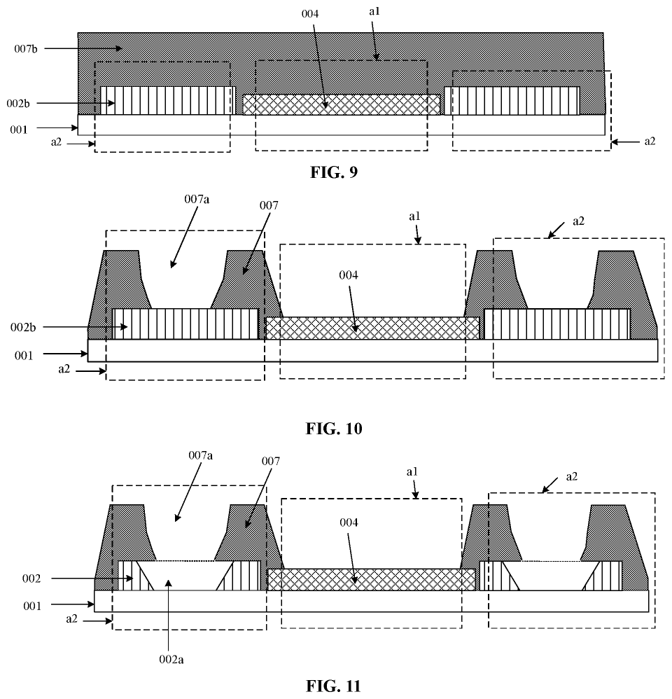

FIG. 1 is a schematic structural diagram of a display substrate according to an embodiment of the present disclosure. As shown in FIG. 1, the display substrate includes: a base substrate 001, an auxiliary electrode layer 002 disposed on the base substrate 001, and a first electrode layer 004, a light-emitting layer 005 and a second electrode layer 006 which are stacked on the base substrate 001 along a direction away from the base substrate 001.

Referring to FIG. 1, a displaying area of the base substrate 001 is provided with a light-emitting area a1 and a non-light-emitting area a2 which surrounds the light-emitting area a1. The auxiliary electrode layer 002 includes an auxiliary electrode pattern 0022 disposed in the non-light-emitting area a2. The auxiliary electrode pattern 0022 is electrically connected to the second electrode layer 006.

In some embodiments, referring to FIG. 1 again, the display substrate further includes a conductive structure 003 disposed in the non-light-emitting area a2 of the base substrate 001, and the conductive structure 003 is in contact with a sidewall of the auxiliary electrode pattern 0022 and the second electrode layer 006, respectively. That is, the second electrode layer 006 is electrically connected to the auxiliary electrode pattern 0022 by the conductive structure 003.

The sidewall of the auxiliary electrode pattern 0022 refers to a surface of the auxiliary electrode pattern which forms an included angle with respect to a bearing surface of the base substrate 001. That is, the sidewall of the auxiliary electrode pattern 0022 refers to side surfaces connecting two opposite surfaces of the auxiliary electrode pattern 0022 which are parallel to the bearing surface of the base substrate 001. The bearing surface of the base substrate 001 refers to a surface of the base substrate 001 which carries various films and layers.

The base substrate 001 is provided with the displaying area, and the light-emitting area a1 in the displaying area is configured to form a structure for emitting light of the display substrate. Illustratively, the light-emitting area a1 is an area capable of emitting light defined by a pixel definition pattern. The light-emitting area a1 may also be referred to as an opening area. Illustratively, FIG. 2 is a schematic top view of a display substrate according to an embodiment of the present disclosure. As shown in FIG. 2, a displaying area of the base substrate 001 is provided with a plurality of light-emitting units M, and each light-emitting unit M includes at least two sub-pixels. The embodiment of the present disclosure is illustrated by taking the light-emitting unit including three sub-pixels as an example. The three sub-pixels include a red sub-pixel R, a green sub-pixel G and a blue sub-pixel B. An orthographic projection of each sub-pixel on the base substrate 001 includes a light-emitting area a1 and a non-light-emitting area a2 which surrounds the light-emitting area a1.

In summary, according to the display substrate provided by the embodiment of the present disclosure, the second electrode layer in the display substrate is electrically connected to the auxiliary electrode pattern disposed in the non-light-emitting area. In this way, while ensuring the light transmittance of the second electrode layer, the resistance of the second electrode layer can be reduced, which enhances the conductive effect of the second electrode layer, thereby improving the display effect of the display substrate.

As an optional implementation, reference is made to FIG. 3 which is a schematic structural diagram of another display substrate according to an embodiment of the present disclosure. As shown in FIG. 3, the auxiliary electrode layer 002 and the first electrode layer 004 are located in the same layer and spaced apart from each other. That is, an orthographic projection of the auxiliary electrode layer 002 onto the base substrate 001 is not overlapped with that of the first electrode layer 004 onto the base substrate 001. The auxiliary electrode layer 002 and the first electrode layer 004 are disposed in the same layer, which means that the auxiliary electrode layer 002 and the first electrode layer 004 are structurally disposed in the same film layer. That is, a surface of the auxiliary electrode layer 002 proximal to the base substrate 001 is coplanar with a surface of the first electrode layer 004 proximal to the base substrate 001. The auxiliary electrode layer 002 and the first electrode layer 004 are spaced apart with each other, meaning that the auxiliary electrode layer 002 is staggered with the first electrode layer 004 for insulation. Referring to FIG. 3, the auxiliary electrode layer 002 is disposed in the non-light-emitting area a2. That is, the auxiliary electrode layer 002 merely includes an auxiliary electrode pattern 0022. The first electrode layer 004 is disposed within the light-emitting area a1. In some embodiments, an orthographic projection of the first electrode layer 004 onto the base substrate 001 covers the light-emitting area a1. Illustratively, the orthographic projection of the first electrode layer 004 onto the base substrate 001 is coincided completely with the light-emitting area a1.

As shown in FIG. 3, the auxiliary electrode pattern 0022 is provided with a first via hole (not shown in FIG. 3), and a conductive structure 003 is at least partially disposed in the first via hole, thereby being in contact with a sidewall of the auxiliary electrode pattern 0022. In this implementation, the sidewall of the auxiliary electrode pattern 0022 is also a sidewall of the first via hole.

In some embodiments, an orthographic projection of an opening on a side, proximal to the base substrate 001, of the first via hole onto the base substrate 001 falls within the orthographic projection of the opening on a side, distal from the side of the base substrate 001, of the first via hole onto the base substrate 001.

In the embodiment of the present disclosure, the first via in the auxiliary electrode pattern 0022 is obtained by etching, and an etching direction X is perpendicular to the bearing surface of the base substrate 001 and facing towards the base substrate 001. That is, the first via hole is obtained by etching the auxiliary electrode pattern 0022 from a side distal from the base substrate 001 to a side proximal to the base substrate 001 to acquire the. As the extension of etching time, the opening on the side, distal from the base substrate 001, of the first via hole becomes larger than the opening on the side, proximal to the side of the base substrate 001, of the first via hole.

In some embodiments, a depth of the first via hole on the auxiliary electrode pattern 0022 ranges from 0.1 μm (micron) to 3 μm. That is, an over-etching amount of the auxiliary electrode pattern 0022 ranges from 0.1 μm to 3 μm. Alternatively, the over-etching amount is a thickness of the auxiliary electrode pattern 0022. In other words, the auxiliary electrode pattern 0022 is etched through. A depth direction of the first via hole is perpendicular to the bearing surface of the base substrate 001.

In some embodiments, referring to FIG. 3, an included angle α (also known as a slope angle, which refers to an acute angle formed by two planes) between the sidewall of the first via hole and the bearing surface of the base substrate 001 ranges from 30° to 60° (degrees). That is, the included angle between a plane in which the sidewall of the auxiliary electrode pattern 0022 is disposed and the bearing surface of the base substrate 001 ranges from 30 ° to 60°. The included angle α between the sidewall of the first via hole and the bearing surface of the base substrate 001 is controlled by adjusting the type of the etching agent and the etching time.

In the embodiment of the present disclosure, the auxiliary electrode layer 002 is made of a metal material with a low resistivity. Illustratively, the auxiliary electrode layer 002 is made of copper (Cu). Alternatively, the auxiliary electrode layer 002 is made of silver (Ag). Alternatively, the auxiliary electrode layer 002 is made of aluminum (Al).

In some embodiments, the first electrode layer 004 includes a reflective metal layer and a transparent electrode layer which are stacked on the base substrate 001 along a direction away from the base substrate 001. The reflective metal layer is made of a metal material having reflective properties. Illustratively, the reflective metal layer is made of Cu, Ag or Al. The transparent electrode layer is made of indium tin oxide (ITO). Light emitted by a light-emitting layer 005 irradiates to the transparent electrode layer and is reflected by the reflective metal layer disposed on a side, proximal to the base substrate, of the transparent electrode layer, and the reflected light is irradiated by the second electrode layer 006, thereby realizing image display.

As another optional implementation, reference is made to FIG. 4 which is a schematic structural diagram of yet another display substrate according to an embodiment of the present disclosure. As shown in FIG. 4, a first electrode layer 004 is disposed on a side, distal from the base substrate 001, of an auxiliary electrode layer 002. The auxiliary electrode layer 002 is made of a metal material having reflective properties, such as Cu, Ag or Al. Moreover, the auxiliary electrode layer 002 includes a reflection pattern 0021 disposed in a light-emitting area a1 and an auxiliary electrode pattern 0022 disposed in a non-light-emitting area a2. A conductive structure 003 is in contact with a sidewall of the auxiliary electrode pattern 0022.

In some embodiments, referring to FIG. 4, an included angle α between a sidewall of the auxiliary electrode pattern 0022 and a bearing surface of the base substrate 001 ranges from 30° to 60°.

In the embodiment of the present disclosure, in the auxiliary electrode layer 002, a reflection pattern 0021 disposed in a light-emitting area a1 is used as a reflective metal layer of the first electrode layer 004, and the auxiliary electrode pattern 0022 disposed in the non-light-emitting area a2 is used as an auxiliary electrode of a second electrode layer 006. Therefore, during the formation of the first electrode layer 004, an ITO transparent electrode is formed directly on a side, distal from the base substrate 001, of the auxiliary electrode layer 002, and there is no need to form an additional reflective metal layer, so as to avoid increasing the complexity of the process for manufacturing the display substrate. Moreover, light emitted by a light-emitting layer 005 irradiates to the ITO transparent electrode and is reflected by a reflection pattern 0021 in the auxiliary layer 002 disposed on a side, proximal to the base substrate, of the ITO transparent electrode, and the reflected light is irradiated by the second electrode layer 006, thereby realizing image display.

In some embodiments, referring to FIG. 4 again, the first electrode layer 004 includes a first electrode pattern 0041 and a second electrode pattern 0042 which are spaced apart with each other. The first electrode pattern 0041 is disposed on a side, distal from the base substrate 001, of the reflection pattern 0021. The second electrode pattern 0042 is disposed on a side, distal from the base substrate 001, of the auxiliary electrode pattern 0021. That is, an area in which the first electrode pattern 0041 is disposed is coincided with or covers the light-emitting area a1, and the second electrode pattern 0042 is disposed in a non-light-emitting area which surrounds the light-emitting area a1.

In some embodiments, an orthographic projection of the second electrode pattern 0042 onto the base substrate 001 covers an orthographic projection of the auxiliary electrode pattern 0022 onto the base substrate 001, such that in the non-light-emitting area a2, a gap is provided with between the light-emitting layer 005 and the sidewall of the auxiliary electrode pattern 0022 in the auxiliary electrode layer 002 after the light-emitting layer 005 is formed by an open mask. In this way, it is possible to prevent the light-emitting layer 005 from blocking the auxiliary electrode pattern 0022 in the auxiliary electrode layer 002, which ensures that the conductive structure 003 is effectively in contact with the auxiliary electrode pattern 0022, thereby ensuring the effective electrical connection between the second electrode layer 006 and the auxiliary electrode pattern 0022 and ensuring the display effect of the display substrate.

In the embodiment of the present disclosure, referring to FIGS. 1 to 4, the conductive structure 003 is made of a conductive adhesive (which is also called a silver conductive adhesive). Owing to that the conductive adhesive is liquid and the conductive structure 003 is made of the conductive adhesive, it can be ensured that the formed conductive structure 003 is capable of being in close contact with the sidewall of the auxiliary electrode pattern 0022, which ensures the effectiveness of the electrical connection between the second electrode layer 006 and the auxiliary electrode pattern 0022.

Alternatively, reference is made to FIG. 5 which is a schematic structural diagram of still another display substrate according to an embodiment of the present disclosure. As shown in FIG. 5, the conductive structure 003 is made of a metal material. When the conductive structure 003 is made of a metal material, the conductive structure 003 is obtained by evaporating the metal material in the non-light-emitting a2 by means of an oblique angle evaporating process.

In the embodiment of the present disclosure, when the auxiliary electrode layer 002 and the first electrode layer 004 are located in the same layer and spaced apart with each other, the conductive structure 003 is obtained by evaporating the metal material in a first via hole in the auxiliary electrode layer 002 by means of the oblique angle evaporating process. When the first electrode layer 004 is disposed on the side, distal from the base substrate 001, of the auxiliary electrode layer 002, the conductive structure 003 is obtained by evaporating the metal material between the reflection pattern 0021 and the auxiliary electrode pattern 0022 in the auxiliary electrode layer 002 by means of the oblique angle evaporating process. Moreover, the obtained conductive structure 003 is in contact with the auxiliary electrode pattern 0022, but not with the reflection pattern 0021.

Referring to FIGS. 3 to 5, a portion of the light-emitting layer 005 is disposed in the non-light-emitting area a2, and a gap is provided between the portion of the light-emitting layer 005 disposed in the non-light-emitting area a2 and the sidewall of the auxiliary electrode pattern 0022. The gap is filled with a conductive structure 003 so as to ensure the contact between the conductive structure 003 and the auxiliary electrode pattern 0022.

Illustratively, referring to FIG. 3 again, a portion of the light-emitting layer 005 is disposed in the first via hole in the auxiliary electrode pattern 0022, and another portion is disposed on a side, distal from the base substrate 001, of the first electrode layer 004. Referring to FIGS. 1, 4 and 5, a portion of the light-emitting layer 005 is disposed between the reflection pattern 0021 and the auxiliary electrode pattern 0022, and another portion is disposed on a side, distal from the base substrate 001, of the first electrode pattern 0041 and a side, distal from the base substrate 001, of the second electrode pattern 0042.

Referring to FIGS. 1 to 5 again, the display substrate further includes a pixel definition pattern 007 disposed on the side, distal from the base substrate 001, of the first electrode layer 004. The pixel definition pattern 007 is configured to define each light-emitting area in the display substrate.

In some embodiments, a portion of the pixel definition pattern 007 disposed in the non-light-emitting area a2 is provided with a second via hole 007a, and the second electrode layer 006 is in contact with the conductive structure 003 by the second via hole 007a.

For a solution in which the auxiliary electrode layer 002 is disposed in the non-light-emitting area a2, i.e., the auxiliary electrode layer 002 merely includes the auxiliary electrode pattern 0022 provided with a first via hole, such the solution shown in FIG. 3, the second via hole 007a is in communication with the first via hole. An orthographic projection of the second via hole 007a onto the base substrate 001 is disposed in an orthographic projection of the first via hole onto the base substrate 001. Thus, a gap is provided between a portion of the light-emitting layer 005 disposed in the non-light-emitting area a2 and the sidewall of the first via hole in the auxiliary electrode pattern 0022. In this way, it is possible to prevent the light-emitting layer 005 from blocking the auxiliary electrode pattern 0022, which ensures that the conductive structure 003 is effectively in contact with the auxiliary electrode pattern 0022, thereby ensuring the effective electrical connection between the second electrode layer 006 and the auxiliary electrode pattern 0022 and ensuring the display effect of the display substrate.

For a solution in which the auxiliary electrode layer 002 includes the reflection pattern 0021 and the auxiliary electrode pattern 0022, such as the solution shown in FIGS. 4 and 5, an orthographic projection of the second via hole 007a onto the base substrate 001 covers orthographic projections of the second electrode pattern 0042 and the auxiliary electrode pattern 0022 onto the base substrate 001. That is, sidewalls of the second electrode pattern 0042 and the auxiliary electrode pattern 0022 are exposed by the second via hole 007a, thereby ensuring that a gap is provided between a portion of the light-emitting layer 005 disposed in the non-light-emitting area a2 and the sidewall of the auxiliary electrode pattern 0022 of the auxiliary electrode layer 002 after the light-emitting layer 005 is formed by an open mask. In this way, it is possible to prevent the light-emitting layer 005 from blocking the auxiliary electrode pattern 0022 in the auxiliary electrode layer 002, which ensures that the conductive structure 003 is effectively in contact with the auxiliary electrode pattern 0022, thereby ensuring the effective electrical connection between the second electrode layer 006 and the auxiliary electrode pattern 0022 and ensuring the display effect of the display substrate.

In the embodiment of the present disclosure, the second electrode layer 006 is made of a metal or a metal alloy. Illustratively, the second electrode layer 006 is made of a metal material such as silver or aluminum. Alternatively, the second electrode layer 006 is made of a metal alloy material such as magnesium silver, magnesium aluminum or magnesium calcium.

In summary, according to the display substrate provided by the embodiment of the present disclosure, the second electrode layer in the display substrate is electrically connected to the auxiliary electrode pattern disposed in the non-light-emitting area. In this way, while ensuring the light transmittance of the second electrode layer, the resistance of the second electrode layer can be reduced, which enhances the conductive effect of the second electrode layer, thereby improving the display effect of the display substrate.

FIG. 6 is a flowchart of a method for manufacturing a display substrate according to an embodiment of the present disclosure, and the method is capable of manufacturing the display substrate according to the aforementioned embodiment. Referring to FIG. 6, the method includes the following steps.

In S101, an auxiliary electrode layer and a first electrode layer are formed on a side of the base substrate.

A displaying area of the base substrate is provided with a light-emitting area and a non-light-emitting area which surrounds the light-emitting area. The auxiliary electrode layer includes an auxiliary electrode pattern disposed in the non-light-emitting area.

In some embodiments, when the auxiliary electrode layer 002 and the first electrode layer 004 are located in the same layer and spaced apart with each other, the auxiliary electrode layer 002 is formed on the base substrate 001 at first, and then the first electrode layer 004 is formed on the base substrate 001. Alternatively, the first electrode layer 004 is formed on the base substrate 001 at first, and then the auxiliary electrode layer 002 is formed on the base substrate 001.

In some embodiments, when the first electrode layer 004 is disposed on a side, distal from the base substrate 001, of the auxiliary electrode layer 002, the auxiliary electrode layer 002 is formed on a side of the base substrate 001 at first, and then the first electrode layer 004 is formed on a side, distal from the base substrate 001, of the auxiliary electrode layer 002.

In S102, a light-emitting layer is formed on a side, distal from the base substrate, of the first electrode layer.

The light-emitting layer 005 is formed by an open mask, and a portion of the light-emitting layer 005 is disposed in the light-emitting area and another portion is disposed in a non-light-emitting area a2.

In S103, a second electrode layer is formed on a side, distal from the base substrate, of the light-emitting layer, wherein the second electrode layer is electrically connected to the auxiliary electrode pattern.

The second electrode layer 006 is electrically connected to the auxiliary electrode pattern 0022 of the auxiliary electrode layer 002. Thus, the resistance of the second electrode layer 006 can be reduced, which enhances the conductive effect of the second electrode layer 006, thereby improving the display effect of the display substrate.

In summary, according to the method for manufacturing the display substrate provided by the embodiment of the present disclosure, the second electrode layer in the formed display substrate is electrically connected to the auxiliary electrode pattern disposed in the non-light-emitting area. In this way, while ensuring the light transmittance of the second electrode layer, the resistance of the second electrode layer can be reduced, which enhances the conductive effect of the second electrode layer, thereby improving the display effect of the display substrate.

As an optional implementation, FIG. 7 is a flowchart of another method for manufacturing a display substrate according to an embodiment of the present disclosure, and the method is capable of manufacturing the display substrate, such as the display substrate shown in FIG. 3, according to the aforementioned embodiment. Referring to FIG. 7, the method includes the following steps.

In S201, an auxiliary electrode film and the first electrode layer, which are located in the same layer, are formed on the base substrate.

Illustratively, FIG. 8 is a schematic structural diagram showing that an auxiliary electrode film and a first electrode layer have been formed according to an embodiment of the present disclosure. Referring to FIG. 8, the auxiliary electrode film 002b and the first electrode layer 004 are located in the same layer. The auxiliary electrode film is disposed in the non-light-emitting area a2. The first electrode layer 004 is disposed in the light-emitting area a1. In some embodiments, an orthographic projection of the first electrode layer 004 onto the base substrate 001 covers the light-emitting area a1. Illustratively, the orthographic projection of the first electrode layer 004 onto the base substrate 001 is coincided completely with the light-emitting area a1.

In the embodiment of the present disclosure, the auxiliary electrode film 002b which is disposed in the non-light-emitting area a2 is formed on the base substrate 001 at first, and then the first electrode layer 004 which is disposed in the light-emitting area a1 is formed on the base substrate 001. Alternatively, the first electrode layer 004 may also be formed on the base substrate 001 at first, and then the auxiliary electrode film 002b is formed on the base substrate 001. The sequence of forming the auxiliary electrode film 002b and the first electrode layer 004 on the base substrate 001 is not limited in the embodiment of the present disclosure.

In some embodiments, the auxiliary electrode film 002b is made of a material with a low resistivity, such as Cu, Ag or Al.

In some embodiments, a process of forming the first electrode layer 004 on the base substrate 001 includes: forming a reflective metal layer on a side of the base substrate 001 at first, and then forming a transparent electrode layer on a side, distal from the base substrate 001, of the reflective metal layer. Thus, the first electrode layer 004 including the reflective metal layer and the transparent electrode layer which are stacked is obtained. The reflective metal layer is made of Cu, Ag or Al, and the transparent electrode layer is made of the ITO material.

In S202, a pixel definition film is formed on a side, distal from the base substrate, of the first electrode layer.

Illustratively, FIG. 9 is a schematic structural diagram showing that a pixel definition film has been formed according to an embodiment of the present disclosure. Referring to FIG. 9, a whole layer of pixel definition film 007b is covered on the base substrate 001.

In S203, patterning process is performed on the pixel definition film, such that a pixel definition pattern is obtained.

Illustratively, FIG. 10 is a schematic structural diagram showing that a pixel definition pattern has been formed according to an embodiment of the present disclosure. Referring to FIG. 10, when patterning process is performed on the pixel definition film 007b, an opening for defining the light-emitting area a1 is formed in the pixel definition film 007b, and a second via hole 007a is formed in a portion of the pixel definition film 007b disposed in the non-light-emitting area a2. The second electrode layer 006 formed subsequently is electrically connected to the auxiliary electrode pattern 0022 by the second via hole 007a.

In some embodiments, patterning process is performed on the pixel definition film 007b by a photolithography process, also known as a mask process, such that the pixel definition pattern 007 is obtained. The photolithography process includes: photoresist coating, exposure, development, etching, photoresist stripping, and the like.

In S204, a first via hole in the auxiliary electrode film is formed by etching the auxiliary electrode film, such that the auxiliary electrode layer is obtained.

The auxiliary electrode layer 002 is an auxiliary electrode pattern 0022. Illustratively, FIG. 11 is a schematic structural diagram showing that an auxiliary electrode layer has been formed according to an embodiment of the present disclosure. The first via hole 002a is formed in the auxiliary electrode film 002b by an etching method, such that the auxiliary electrode layer 002 is obtained. The first via hole 002a is disposed in the non-light-emitting area a2. An orthographic projection of the second via hole 007a in the pixel definition pattern 007 onto the base substrate 001 falls within the orthographic projection of the first via hole 002a onto the base substrate 001. Thus, a gap is provided between a portion of the light-emitting layer 005 disposed in the non-light-emitting area a2 and the sidewall of the first via hole 002a in the auxiliary electrode layer 002 after the light-emitting layer 005 is subsequently formed by an open mask. In this way, it is possible to prevent the subsequently prepared light-emitting layer 005 from blocking the auxiliary electrode layer 002, which ensures that the subsequently formed conductive structure 003 is capable of being in contact effectively with the auxiliary electrode layer 002, thereby ensuring the effective electrical connection between the second electrode layer 006 and the auxiliary electrode layer 002 and ensuring the display effect of the display substrate.

In the embodiment of the present disclosure, the auxiliary electrode film 002b is etched by a wet etching method. Alternatively, the auxiliary electrode film 002b is etched by a dry etching method.

The wet etching method refers to an etching method by which an object to be etched is stripped off by a chemical reaction between the etching agent and the object to be etched. The wet etching is isotropic etching which means that an etching agent etches downwards at approximately the same rate as those in other directions. The dry etching method refers to an etching method by which the plasma reacts with the object to be etched to form a volatile substance, or that the object to be etched is stripped off by directly bombardment on the surface of the object to be etched. The dry etching is anisotropic etching in which the etching rate of an etching agent in one direction is much higher than those in other directions.

In some embodiments, referring to FIG. 11 again, an orthographic projection of an opening on a side, proximal to the base substrate 001, of the first via hole 002a onto the base substrate 001 falls within the orthographic projection of the opening on the side, distal from the base substrate 001, of the first via hole 002a onto the base substrate 001. In this way, it is possible to prevent the light-emitting layer 005 from blocking the auxiliary electrode layer 002 during the subsequent formation of the light-emitting layer 005 by an open mask subsequently, which ensures that the conductive structure 003 formed subsequently is capable of being in contact effectively with the auxiliary electrode layer 002, thereby ensuring the effective electrical connection between the second electrode layer 006 and the auxiliary electrode layer 002.

In some embodiments, an included angle α between a sidewall of the first via hole 002a and a plane, proximal to the auxiliary electrode layer 002, of the base substrate 001 ranges from 30° to 60°. The included angle α is controlled by adjusting the etching solution and the etching time.

In S205, a light-emitting layer is formed on a side, distal from the base substrate, of the first electrode layer.

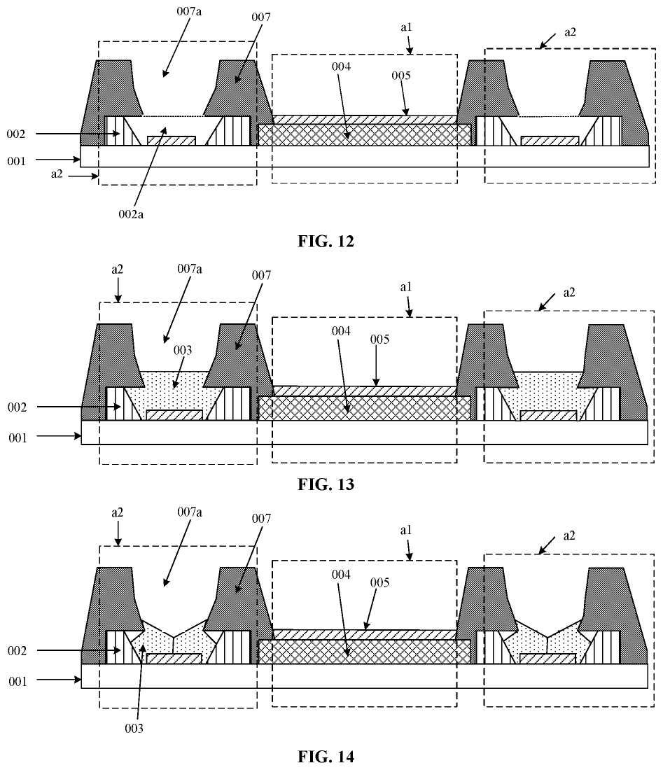

The light-emitting layer 005 is formed on the side, distal from the base substrate 001, of the first electrode layer 004 by the open mask. Illustratively, FIG. 12 is a schematic structural diagram showing that a light-emitting layer has been formed according to an embodiment of the present disclosure. Referring to FIG. 12, a portion of the light-emitting layer 005 is disposed in the light-emitting area a1 and another portion is disposed in the first via hole 002a. A gap is provided between the portion of the light-emitting layer 005 disposed in the first via hole 002a and a sidewall of the auxiliary electrode layer 002. The gap is filled with a subsequently formed conductive structure 003, so as to facilitate the contact between the second electrode layer 006 and the conductive structure 003.

In some embodiments, the light-emitting layer 005 is prepared by a evaporating process, or the light-emitting layer 005 is prepared by the evaporating process combined with a solution method. Usually, the light-emitting layer 005 is a whole-layer structure.

In S206, the conductive structure is formed in the first via hole.

Illustratively, FIG. 13 is a schematic structural diagram showing that a conductive structure has formed according to an embodiment of the present disclosure. Referring to FIG. 13, the conductive structure 003 is made of a conductive adhesive. In the embodiment of the present disclosure, the conductive adhesive is filled in the first via hole 002a at first, and then the conductive adhesive is solidified by heating or ultraviolet (UV) irradiation, that is, the conductive adhesive is cured. Owing to that the conductive adhesive is liquid, and the conductive structure 003 is made of the conductive adhesive, it can be ensured that the formed conductive structure 003 is capable of being in close contact with the sidewall of the auxiliary electrode layer 002, which ensures the effectiveness of the electrical connection between the second electrode layer 006 and the auxiliary electrode layer 002.

In some embodiments, the conductive adhesive is filled into the first via hole 002a by printing and is in contact with the sidewall of the first via hole 002a.

For another example, FIG. 14 is a schematic structural diagram showing that another conductive structure has been formed according to an embodiment of the present disclosure. Referring to FIG. 14, the conductive structure 003 is also made of a metal material. The conductive structure 003 is obtained by evaporating a metal material at a gap between the portion of the light-emitting layer 005 disposed in the first via hole 002a and the sidewall of the auxiliary electrode layer 002, by an oblique angle evaporating process being adopted.

In S207, a second electrode layer is formed on a side, distal from the base substrate, of the light-emitting layer, the second electrode layer is in contact with the conductive structure.

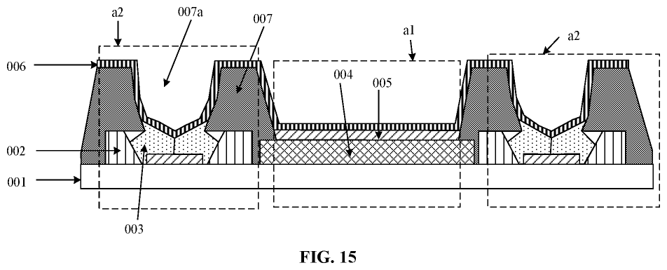

Illustratively, FIG. 15 is a schematic structural diagram of still yet another display substrate according to an embodiment of the present disclosure. Referring to FIGS. 3 and 15, the second electrode layer 006 is disposed on a side, distal from the base substrate 001, of the light-emitting layer 005. The second electrode layer 006 is electrically connected to the auxiliary electrode layer 002 by the conductive structure 003 (which is made of a conductive adhesive in FIG. 3 and is made of a metal material in FIG. 15). Thus, the resistance of the second electrode layer 006 can be reduced and the conductive effect of the second electrode layer 006 can be enhanced to improve the display effect of the display substrate.

In the embodiment of the present disclosure, the second electrode layer 006 is made of a metal or a metal alloy. Illustratively, the second electrode layer 006 is made of a metal material such as silver or aluminum. Alternatively, the second electrode layer 006 is made of a metal alloy material such as magnesium silver, magnesium aluminum or magnesium calcium.

In some embodiments, the second electrode layer 006 is prepared by a magnetron sputtering method or by an evaporating method. When the magnetron sputtering method is adopted to prepare the second electrode layer 006, a protective layer is formed on a side, distal from the base substrate 001, of the light-emitting layer 004 before the second electrode layer 006 is formed, so as to avoid damage to the light-emitting layer 004 during the preparation of the second electrode layer 006 by the magnetron sputtering method. The material for preparing the protective layer includes copper phthalocyanine (CuPc).

In summary, according to the method for manufacturing the display substrate provided by the embodiment of the present disclosure, the second electrode layer in the display substrate is electrically connected to the auxiliary electrode pattern disposed in the non-light-emitting area. In this way, while ensuring the light transmittance of the second electrode layer, the resistance of the second electrode layer can be reduced, which enhances the conductive effect of the second electrode layer, thereby improving the display effect of the display substrate.

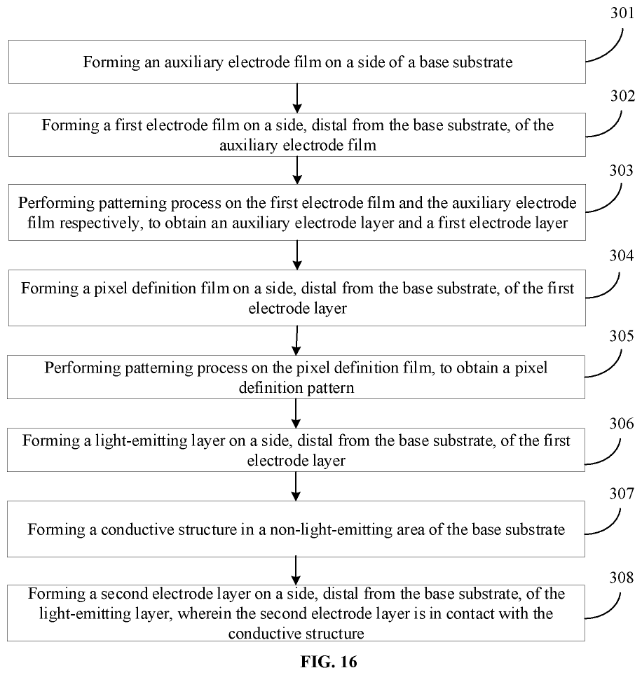

As another optional implementation, FIG. 16 is a flowchart of yet another method for manufacturing a display substrate according to an embodiment of the present disclosure. The method is capable of manufacturing the display substrate according to the aforementioned embodiment. As shown in FIG. 16, the method includes the following steps.

In S301, an auxiliary electrode film is formed on a side of the base substrate.

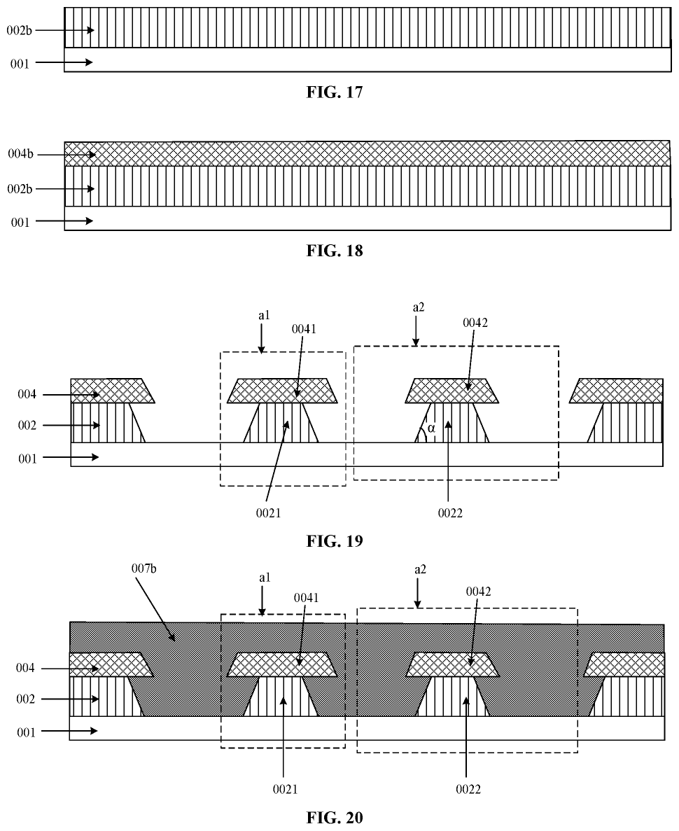

Illustratively, FIG. 17 is a schematic structural diagram showing that an auxiliary electrode film has been formed according to an embodiment of the present disclosure. Referring to FIG. 17, an auxiliary electrode film 002b is disposed on a side of the base substrate 001.

In some embodiments, the auxiliary electrode film 002b is made of a metal material having reflective properties. Illustratively, the auxiliary electrode film 002b is made of Cu, Ag or Al.

In S302, a first electrode film is formed on a side, distal from the base substrate, of the auxiliary electrode film.

Illustratively, FIG. 18 is a schematic structural diagram showing that a first electrode film has formed according to an embodiment of the present disclosure. Referring to FIG. 18, both a whole layer of the first electrode film 004b and a whole layer of the auxiliary electrode film 002b are covered on the base substrate 001. In some embodiments, the first electrode film 004b is an ITO transparent electrode film.

In S303, patterning process is performed on the first electrode film and the auxiliary electrode film respectively, such that the auxiliary electrode layer and the first electrode layer are obtained.

Illustratively, FIG. 19 is a schematic structural diagram showing that an auxiliary electrode layer and a first electrode layer have been formed according to an embodiment of the present disclosure. Referring to FIG. 19, the auxiliary electrode layer 002 includes: a reflection pattern 0021 disposed in a light-emitting area a1 and an auxiliary electrode pattern 0022 disposed in a non-light-emitting area a2. The conductive structure 003 subsequently formed is in contact with a sidewall of the auxiliary electrode pattern 0022. The reflection pattern 0021 is configured to reflect light emitted by the light-emitting layer 005. The reflected light is irradiated by the second electrode layer 006, thereby realizing image display. The non-light-emitting area a2 surrounds the light-emitting area a1.

Referring to FIG. 19 again, the first electrode layer 004 includes a first electrode pattern 0041 and a second electrode pattern 0042 which are spaced apart with each other. The first electrode pattern 0041 is formed on a side, distal from the base substrate 001, of the reflection pattern 0021. The second electrode pattern 0042 is formed on a side, distal from the base substrate 001, of the auxiliary electrode pattern 0021. That is, the first electrode pattern 0041 is formed in the light-emitting area a1, and an area in which the first electrode pattern 0041 is disposed is coincided with or covers the light-emitting area a1, and the second electrode pattern 0042 is formed in a non-light-emitting area a2 which surrounds the light-emitting area a1.

In some embodiments, an orthographic projection of the second electrode pattern 0042 onto the base substrate 001 covers an orthographic projection of the auxiliary electrode pattern 0022 onto the base substrate 001, such that a gap between a portion of the light-emitting layer 005 disposed in the non-light-emitting area a2 and the auxiliary electrode pattern 0022 in the auxiliary electrode layer 002 is provided after the light-emitting layer 005 is formed subsequently by an open mask. In this way, it is possible to prevent the light-emitting layer 005 from blocking the auxiliary electrode pattern 0022 in the auxiliary electrode layer 002, which ensures that the conductive structure 003 is effectively in contact with the auxiliary electrode pattern 0022, thereby ensuring the effective electrical connection between the second electrode layer 006 and the auxiliary electrode pattern 0022 and ensuring the display effect of the display substrate.

In the embodiment of the present disclosure, patterning process is performed on the first electrode film 004b and the auxiliary electrode film 002b by etching to form the first electrode layer 004 and the auxiliary electrode layer 002. For the implementing procedures of the etching process, reference is made to S204, which is not be repeated herein.

In some embodiments, the included angle α between a sidewall of the auxiliary electrode pattern 0022 and a bearing surface of the base substrate 001 ranges from 30° (degrees) to 60°. The included angle α between the sidewall of the auxiliary electrode pattern 0022 and the bearing surface of the base substrate 001 is controlled by adjusting the type of the etching agent and the etching time.

In order to ensure that an orthographic projection of the first electrode layer 004 onto the base substrate 001 covers the orthographic projection of the auxiliary electrode layer 002 onto the base substrate 001, different etching agents may be adopted to etch the first electrode film 004b and the auxiliary electrode film 002b, such that the auxiliary electrode film 002b is not be etched during the etching of the first electrode film 004b and the first electrode film 004b is not be etched during the etching of the auxiliary electrode film 002b.

In 5304, a pixel definition film is formed on a side, distal from the base substrate, of the first electrode layer.

Illustratively, FIG. 20 is a schematic structural diagram showing that another pixel definition film has been formed according to an embodiment of the present disclosure. Referring to FIG. 20, a whole layer of the pixel definition film 007b is covered on the base substrate 001.

In S305, patterning process is performed on the pixel definition film, such that a pixel definition pattern is obtained.

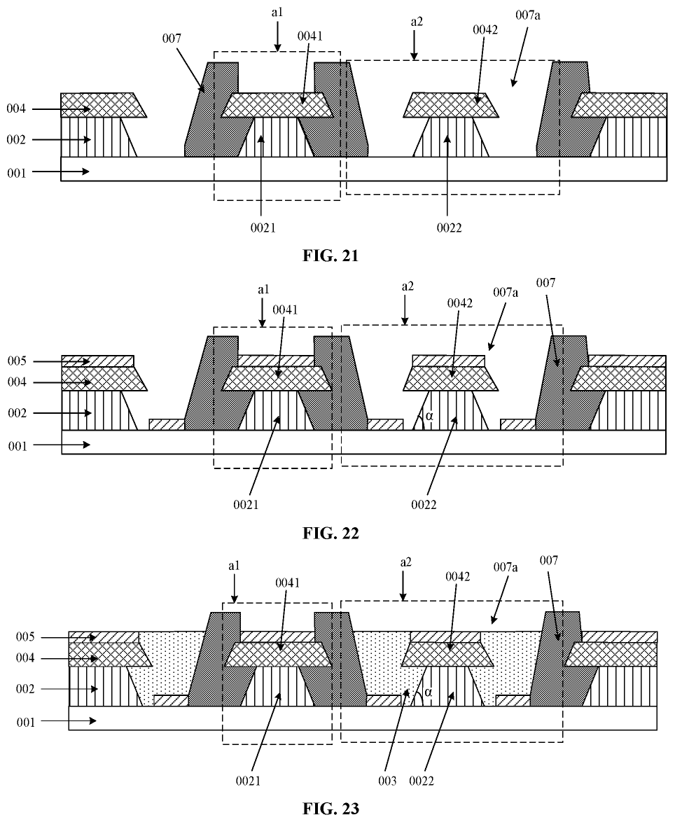

Illustratively, FIG. 21 is a schematic structural diagram showing that another pixel definition pattern has been formed according to an embodiment of the present disclosure. Referring to FIG. 21, during the performing the patterning process on the pixel definition film 007b, an opening for defining the light-emitting area a1 is formed in the pixel definition film 007b, and a second via hole 007a is formed in a portion of the pixel definition film 007b disposed in the non-light-emitting area a2. The second electrode layer 006 is in contact with the conductive structure 003 via a second via hole 007a.

In some embodiments, patterning process is performed on the pixel definition film 007b by a photolithography process, such that a pixel definition pattern 007 is obtained.

In S306, a light-emitting layer is formed on a side, distal from the base substrate, of the first electrode layer.

Illustratively, FIG. 22 is a schematic structural diagram showing that another light-emitting layer has been formed according to an embodiment of the present disclosure. The light-emitting layer 005 is formed on the side, distal from the base substrate 001, of the first electrode layer 004 by an open mask. Referring to FIG. 22, the light-emitting layer 005 is disposed in a portion of the non-light-emitting area a2, and a gap is provided between the light-emitting layer 005 and the sidewall of the auxiliary electrode pattern 0022. The gap is filled with a conductive structure 003 subsequently formed, so as to facilitate the contact between the second electrode layer 006 and the conductive structure 003. The light-emitting layer 005 is prepared by an evaporating process, or the light-emitting layer 005 is prepared by the evaporating process in combination with a solution method.

In S307, the conductive structure is formed in the non-light-emitting area of the base substrate.

Illustratively, FIG. 23 is a schematic structural diagram showing that yet another conductive structure has been formed according to an embodiment of the present disclosure. Referring to FIG. 23, the conductive structure 003 is made of a conductive adhesive. Alternatively, the conductive adhesive is filled in the non-light-emitting area a2 at first, and then the conductive adhesive is solidified by heating or UV irradiation. Owing to that the conductive adhesive is liquid and the conductive structure 003 is made of the conductive adhesive, it can be ensured that the formed conductive structure 003 is capable of being in close contact with the sidewall of the auxiliary electrode pattern 0022, which ensures the effectiveness of the electrical connection between the second electrode layer 006 and the auxiliary electrode pattern 0022.

In some embodiments, the conductive adhesive is filled into the non-light-emitting area a2 by printing. The conductive adhesive is in contact with a sidewall of the auxiliary electrode pattern 0022 of the auxiliary electrode layer 002 disposed in the non-light-emitting area a2.

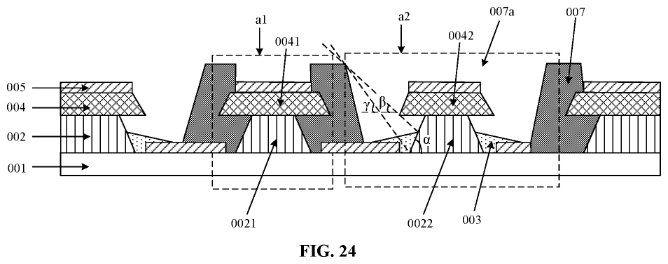

For another example, FIG. 24 is a schematic structural diagram showing that still another conductive structure has been formed according to an embodiment of the present disclosure. Referring to FIG. 24, the conductive structure 003 is made of a metal material. In order to ensure that the conductive structure 003 is evaporated in a gap between a portion of the light-emitting layer 005 disposed in the non-light-emitting area a2 and a sidewall of the auxiliary electrode layer 002, the evaporation angle θ shall meet the following condition: being greater than a first angle β and less than a second angle γ, that is, β<θ<γ. The evaporation angle θ refers to an included angle between an evaporating direction of an evaporation source and a bearing surface of the base substrate 001. The first angle β refers to an included angle between a line connecting an edge on a side, distal from the base substrate 001 and proximal to non-light-emitting area a2, of the pixel definition pattern 007 with an edge on a side, proximal to the base substrate 001 and proximal to the light-emitting area a1, of the first electrode layer 004, and a bearing surface of the base substrate 001. The second angle γ refers to an included angle between a line connecting the edge on the side, distal from the base substrate 001 and proximal to non-light-emitting area a2, of the pixel definition pattern 007 with the edge on a side, proximal to the base substrate 001 and proximal to the light-emitting area a1, of the auxiliary electrode layer 002, and a bearing surface of the base substrate 001.

In S308, a second electrode layer is formed on a side, distal from the base substrate, of the light-emitting layer, the second electrode layer is in contact with the conductive structure.

In some embodiments, referring to FIG. 4, the conductive structure 003 is made of a conductive adhesive. Alternatively, referring to FIG. 5, the conductive structure 003 is made of a metal material. The second electrode layer 006 is disposed on a side, distal from the base substrate 001, of the light-emitting layer 005. The second electrode layer 006 is electrically connected to the auxiliary electrode pattern 0022 by the conductive structure 003, the resistance of the second electrode layer 006 can be reduced, which enhances the conductive effect of the second electrode layer 006, thereby improving the display effect of the display substrate.

For the forming process of the second electrode layer 006, reference is made to the aforementioned S207, which is not be repeated herein.

In summary, according to the method for manufacturing the display substrate provided by the embodiment of the present disclosure, the second electrode layer in the display substrate is electrically connected to the auxiliary electrode pattern disposed in the non-light-emitting area. In this way, while ensuring the light transmittance of the second electrode layer, the resistance of the second electrode layer can be reduced, which enhances the conductive effect of the second electrode layer, thereby improving the display effect of the display substrate.

The embodiment of the present disclosure further provides a display device which includes a display substrate according to the aforementioned embodiment and a driving circuit configured to drive the display substrate. The display device is any product or component with a display function, such as a liquid crystal display (LCD) panel, an electronic paper, an organic light emitting diode (OLED) panel, an active matrix organic light emitting diode (AMOLED) panel, a mobile phone, a tablet computer, a television, a display, a notebook computer, a digital photo frame or a navigator.

Described above are merely exemplary embodiments of the present disclosure, but are not intended to limit the present disclosure. Any modifications, equivalent replacements, improvements and the like made within the spirit and principles of the present disclosure should be included within the scope of protection of the present disclosure.

What is claimed is:

1. A display substrate, comprising:
a base substrate, wherein a displaying area of the base substrate is provided with a light-emitting area and a non-light-emitting area surrounding the light-emitting area;
an auxiliary electrode layer on the base substrate, wherein the auxiliary electrode layer comprises an auxiliary electrode pattern in the non-light-emitting area; and
a first electrode layer, a light-emitting layer and a second electrode layer which are stacked on the base substrate along a direction away from the base substrate,
wherein the auxiliary electrode pattern is electrically connected to the second electrode layer.

2. The display substrate according to claim 1, further comprising a conductive structure disposed in the non-light-emitting area of the base substrate, wherein the conductive structure is in contact with a sidewall of the auxiliary electrode pattern and with the second electrode layer, respectively.

3. The display substrate according to claim 2, wherein an included angle between the sidewall of the auxiliary electrode pattern and a carrying surface of the base substrate ranges from 30° to 60°.

4. The display substrate according to claim 2, wherein the conductive structure is made of a conductive adhesive.

5. The display substrate according to claim 2, wherein a gap is provided between a portion of the light-emitting layer located in the non-light-emitting area and the sidewall of the auxiliary electrode pattern, and the gap is filled with the conductive structure.

6. The display substrate according to claim 2, wherein the auxiliary electrode layer and the first electrode layer are located in a same layer and spaced apart from each other; and
the auxiliary electrode pattern is provided with a first via hole, and the conductive structure is at least partially disposed in the first via hole.

7. The display substrate according to claim 6, wherein an orthographic projection of an opening on a side, proximal to the base substrate, of the first via hole onto the base substrate is located within an orthographic projection of an opening on a side, distal from the base substrate, of the first via hole onto the base substrate.

8. The display substrate according to claim 6, further comprising a pixel definition pattern on a side, distal from the base substrate, of the first electrode layer, wherein the pixel definition pattern is provided with a second via hole which is communicated with the first via hole; and
an orthographic projection of the second via hole onto the base substrate is located within the orthographic projection of the first via hole onto the base substrate.

9. The display substrate according to claim 6, wherein the first electrode layer comprises a reflective metal layer and a transparent electrode layer which are stacked on the base substrate along the direction away from the base substrate.

10. The display substrate according to claim 7, further comprising a pixel definition pattern on a side, distal from the base substrate, of the first electrode layer, wherein the pixel definition pattern is provided with a second via hole which is communicated with the first via hole, an area of the orthographic projection of the first via hole onto the base substrate is larger than an area of the orthographic projection of the second via hole onto the base substrate, and the orthographic projection of the second via hole onto the base substrate is located within the orthographic projection of the first via hole onto the base substrate; and
the first electrode layer comprises a reflective metal layer and a transparent electrode layer which are stacked along the direction away from the base substrate.

11. The display substrate according to claim 1, wherein the first electrode layer is located on a side, distal from the base substrate, of the auxiliary electrode layer, and the auxiliary electrode layer further comprises a reflection pattern disposed in the light-emitting area.

12. The display substrate according to claim 11, wherein the first electrode layer comprises a first electrode pattern and a second electrode pattern which are spaced apart with each other; wherein
the first electrode pattern is located on a side, distal from the base substrate, of the reflection pattern, and the second electrode pattern is located on a side, distal from the base substrate, of the auxiliary electrode pattern, and an orthographic projection of the second electrode pattern onto the base substrate covers an orthographic projection of the auxiliary electrode pattern onto the base substrate.

13. A method for manufacturing a display substrate, comprising:
forming an auxiliary electrode layer and a first electrode layer on a base substrate, wherein a displaying area of the base substrate is provided with a light-emitting area and a non-light-emitting area surrounding the light-emitting area, and the auxiliary electrode layer comprises an auxiliary electrode pattern located in the non-light-emitting area;
forming a light-emitting layer on a side, distal from the base substrate, of the first electrode layer; and
forming a second electrode layer on a side, distal from the base substrate, of the light-emitting layer, wherein the second electrode layer is electrically connected to the auxiliary electrode pattern.

14. The method according to claim 13, wherein forming the auxiliary electrode layer and the first electrode layer on the base substrate comprises:
forming an auxiliary electrode film and the first electrode layer, which are located in a same layer, on the base substrate, wherein the auxiliary electrode film is located in the non-light-emitting area; and
forming a first via hole in the auxiliary electrode film by etching the auxiliary electrode film, to obtain the auxiliary electrode layer.

15. The method according to claim 13, wherein forming the auxiliary electrode layer and the first electrode layer on the base substrate comprises:
forming an auxiliary electrode film on the base substrate;
forming a first electrode film on a side, distal from the base substrate, of the auxiliary electrode film; and
performing patterning process on the first electrode film and the auxiliary electrode film respectively, to obtain the auxiliary electrode layer and the first electrode layer;
wherein the auxiliary electrode layer further comprises a reflection pattern disposed in the light-emitting area.

16. The method according to claim 13, wherein, after forming the light-emitting layer on the side, distal from the base substrate, of the first electrode layer, the method further comprises:
forming a conductive structure in the non-light-emitting area of the base substrate, wherein the conductive structure is in contact with a sidewall of the auxiliary electrode pattern, and the second electrode layer is electrically connected to the auxiliary electrode pattern by the conductive structure.

17. The method according to claim 16, wherein forming the conductive structure in the non-light-emitting area of the base substrate comprises:
filling a conductive adhesive in the non-light-emitting area; and
forming the conductive structure by curing the conductive adhesive.

18. The method according to claim 16, wherein forming the conductive structure in the non-light-emitting area of the base substrate comprises:
evaporating a metal material at a gap between a portion of the light-emitting layer located in the non-light-emitting area and a sidewall of the auxiliary electrode layer by an oblique angle evaporating process, to obtain the conductive structure.

19. The method according to claim 13, wherein, before forming the light-emitting layer on the side, distal from the base substrate, of the first electrode layer, the method further comprises:
forming a pixel definition film on a side, distal from the base substrate, of the first electrode layer; and
performing patterning process on the pixel definition film, to obtain the pixel definition pattern, wherein a portion of the pixel definition pattern located in the non-light-emitting area is provided with a second via hole, and the second electrode layer is electrically connected to the auxiliary electrode pattern through the second via hole.

20. A display device, comprising a display substrate; wherein the display substrate comprises:
a base substrate, wherein a displaying area of the base substrate is provided with a light-emitting area and a non-light-emitting area surrounding the light-emitting area;
an auxiliary electrode layer on the base substrate, wherein the auxiliary electrode layer comprises an auxiliary electrode pattern in the non-light-emitting area; and
a first electrode layer, a light-emitting layer and a second electrode layer which are stacked on the base substrate along a direction away from the base substrate,
wherein the auxiliary electrode pattern is electrically connected to the second electrode layer.
